(19) United States
(12) Patent Application Publication
(10) Pub. No.: US 2026/0371964 A1
(43) Pub. Date: Nov. 19, 2026

(54) LOW-NOISE HIGH ELECTRON MOBILITY TRANSISTOR MANUFACTURING VIA ATOMIC LAYER ETCHING

(71) Applicant: California Institute of Technology, Pasadena, CA (US)

(72) Inventors: Anthony J. Ardizzi, Pasadena, CA (US); Austin Minnich, San Marino, CA (US); Mete Bayrak, Pasadena, CA (US); Kieran A. Cleary, Bishop, CA (US)

(73) Assignee: California Institute of Technology, Pasadena, CA (US)

(21) Appl. No.: 19/664,293

(22) Filed: Apr. 30, 2026

Related U.S. Application Data
(60) Provisional application No. 63/797,579, filed on Apr. 30, 2025.

(51) Int. Cl. H10P 50/24; H01J 37/32; H10D 30/47; H10P 72/00

(52) U.S. Cl. CPC H10P 50/246; H01J 37/32357; H10D 30/471; H10P 72/0421; H01J 2237/334

(57) ABSTRACT

An ALE process for semiconductors such as InGaAs comprising of sequential hydrogen radical and oxygen gas exposures is reported. An etch rate of 0.095 Å cycle-1 is observed for InGaAs and both half-cycles exhibit self-limiting behavior. The process preserves the atomic-scale smoothness of the original epitaxial wafer after 200 cycles of ALE. The process can be used for applications in the fabrication of InP HEMTs with improved high-frequency (e.g., microwave) performance and gain stability and yield.

### CROSS REFERENCE TO RELATED APPLICATIONS

This application claims the benefit under 35 U.S.C. Section 119(e) of U.S. Provisional Application No. 63/797,579, filed Apr. 30, 2025, by Anthony J. Ardizzi; Austin Minnich; Mete Bayrak; and Kieran A. Cleary, entitled “LOW-NOISE HIGH ELECTRON MOBILITY TRANSISTOR MANUFACTURING VIA ATOMIC LAYER ETCHING,” (attorney docket no. CIT-9307-P), which application is incorporated by reference herein.

### STATEMENT REGARDING FEDERALLY SPONSORED RESEARCH AND DEVELOPMENT

This Invention was made with Government support under Agreement No. N00164-19-9-0001, awarded by NSWC Crane Division. The Government has certain rights in the Invention.

### BACKGROUND OF THE INVENTION

### Field of the Invention

The present disclosure relates to atomic layer etching processes for III-V compound semiconductors, methods of performing the same, and applications in InP high electron mobility transistor fabrication.

### Description of the Related Art

III-V compound semiconductors such as InGaAs and InAlAs are of high importance for both fundamental science and applications. In particular, high electron mobility transistors (HEMTs) based on InGaAs/InAlAs quantum wells are widely used for remote sensing [1], radio astronomy [2-4], communications [5,6], and increasingly quantum computing due to their outstanding noise performance [7-11]. A critical step in HEMT fabrication is the gate recess etch in which the cap (consisting of highly doped InGaAs) is etched down to the InAlAs barrier so that an electric current flows through the channel. For optimal noise performance, the gate-barrier junction should be as close as possible to the conducting channel while maintaining a low leakage current (A mm-1) [12, 13]. As a result, the etch depth precision and electrical quality of the etched surface in the gate recess are of critical importance. Any heterogeneities, for instance from local variations in etch rate across the wafer, degrade yield. Further, etch-induced damage limits the achievable degree of vertical scaling, which in turn sets high frequency performance limits [14]. Etch damage also leads to the formation of electrical traps at the Schottky gate-barrier junction that causes gain instabilities [15-17].

Atomic layer etching (ALE) is an emerging nanofabrication technique that consists of a set of sequential and self-limiting half-steps that together produce etching [18]. An ALE process generally consists of a modification step followed by a selective removal of the modified surface layer; the removal step can be either isotropic or anisotropic depending on the mechanism. Anisotropic (directional) ALE was first demonstrated and takes advantage of the difference in surface binding energy between the original and modified surface to sputter only the modified layer with low-energy ions or neutral atoms [19]. ALE based on a neutral Ne beam for InP was reported and utilized for the removal of an InP etch stop in HEMT fabrication [20-22]. In 2015, isotropic ALE based on thermal ligand-exchange reactions without plasma was first reported [23]. Since then, several other approaches for thermal ALE have been reported [24].

Thermal ALE of InGaAs has previously been demonstrated using vapor HF to form fluoride compounds and ligand-exchange for volatilization using dimethylaluminum chloride (DMAC) [25]. This process had an etch per cycle (EPC) of around 0.1 Å cycle-1 and was used to fabricate an InGaAs FinFET with record performance [26]. Directional ALE of InGaAs has also been explored using chlorine radicals as the modification step and low energy Ar ions to sputter the modified surface layer [27]. This process was reported to achieve an EPC of 1.1 Å cycle-1 and lower surface roughness than was achieved with reactive ion etching. Despite these advances, what is needed are processes which have higher EPC than the known thermal process, preserve the stoichiometry of the ternary alloy, and induce as little surface damage as possible remain of interest. The present disclosure satisfies this need.

### BRIEF DESCRIPTION OF THE DRAWINGS

Referring now to the drawings in which like reference numbers represent corresponding parts throughout:

FIG. 1. Schematic of the ALE process. InGaAs is oxidized by oxygen gas (light orange dots). This oxide layer is then removed by hydrogen radicals (blue dots).

FIG. 2. EPC versus cycle number for 45 s of 02 gas per cycle (blue squares), 60 s of H2 radicals (red circles), and both 45 s of 02 gas and 60 s of H2 radicals per cycle (purple triangles). All processes were carried out at 350 °C.

FIG. 3A shows 02 gas saturation curve obtained for a fixed H2 radical exposure of 60 s.

FIG. 3B shows H2 radical saturation curve obtained for a fixed O2 gas exposure of 45 s. The chamber temperature, pressure, pump and purge times were held constant for these plots.

FIGS. 4A-4C. Surface XPS spectra for (FIG. 4A) Ga2p, (FIG. 4B) In3d, and (FIG. 4C) As3d peaks. The spectra are shown for the original sample (top) and the etched sample (bottom). The measured spectra (gray dots) and fit spectra envelope (black line) are given in arbitrary units (a.u.) versus their binding energy (eV).

FIGS. 5A-5B. Atomic concentration of In, As, Ga, O, and C as a function of Ar milling time(s) for (FIG. 5A) original sample with native oxide, (FIG. 5B) sample with 200 cycles of ALE.

FIGS. 6A-6C. Surface height map of (FIG. 6A) original, (FIG. 6B) wet etched, and (FIG. 6C) ALE InGaAs. The RMS roughnesses are (FIG. 6A) nm, (FIG. 6B) 0.51 nm, and (FIG. 6C) 0.13 nm, respectively.

FIG. 7. PSD obtained from AFM scans of original (green dashed), wet etched (solid red), and ALE InGaAs (blue dashed).

FIG. 8 is a flowchart illustrating a method of etching.

FIG. 9 is a flowchart illustrating a method of making a device.

FIG. 10. HEMT with recess fabricated according to embodiments described herein.

FIG. 11. Wafer with a plurality of HEMTs including recesses fabricated according the embodiments described herein. Not to scale.

FIGS. 12A and 12B. Example etching apparatus, wherein FIG. 12A is an embodiment with remote Inductively Coupled Plasma (ICP) source for the hydrogen radicals, and FIG. 12B illustrates an embodiment using thermal cracking using a hot filament.

FIG. 13. Example hardware environment.

### SUMMARY OF THE INVENTION

An ALE process for semiconductor etching based on sequential atomic hydrogen/hydrogen radicals and oxygen gas exposures has been developed. Test samples remain atomically smooth after many cycles of ALE. This process can be integrated into the InP HEMT fabrication flow as the gate recess etch step in order to improve microwave performance metrics and device yield.

While the ALE recipe has already been demonstrated to exhibit optimal etching results when applied to InGaAs, the Hydrogen/Oxygen recipe is expected to be widely applicable to most oxidizing III-V semi-conductors due to the universality of III-V oxide growth and subsequent removal using hydrogen exposure. Further embodiments of this invention include optimizations of parameters such as process temperature, oxygen and hydrogen exposure times, and vacuum chamber purge times to achieve the highest performance metrics and yield for different III-V devices.

Illustrative embodiments of the inventive subject matter include, but are not limited to, the following.
1. A method of atomic layer etching of a III-V semiconductor material, comprising:
(a) performing a first half-cycle comprising exposing a surface of the III-V semiconductor material to an oxidizing agent to form an oxide layer on the surface; and
(b) performing a second half-cycle comprising exposing the oxide layer to hydrogen radicals to remove the oxide layer from the surface to form an etched surface; wherein the first half-cycle and the second half-cycle are each self-limiting.
2 The method of clause 1, further comprising depositing a passivation layer on the etched surface, or passivating the etched surface, using atomic layer deposition in situ with the atomic layer etching.
3. The method of clause 1 or 2, wherein the passivation layer comprises a high k dielectric layer where k is at least 9.
4. The method of any of the clauses 1-3, wherein the III-V semiconductor material comprises at least one of InGaAs, InAlAs, or InP.
5. The method of any of the clauses 1-4, wherein the oxidizing agent is at least one of oxygen gas, ozone, or remote oxygen plasma.
6. The method of any of the clauses 1-5, further comprising a hydrogen plasma comprising the hydrogen radicals.
7. The method of any of the clauses 1-6, wherein the hydrogen radicals consist essentially of, or consist of, or are, hydrogen atoms or dissociated neutral hydrogen molecules.
8. The method of any of the clauses 1-7, wherein the hydrogen radicals are generated by:
an inductively coupled plasma source operated in a pseudo-remote plasma configuration that reduces direct ion impingement on the III-V semiconductor surface,
thermal cracking with a hot filament, or
a microwave plasma source
9. The method of any of the clauses 1-8, wherein the method is performed at a process temperature between about 200 degrees Celsius and about 400 degrees Celsius.
10. The method of any of the clauses 1-9, wherein the etch per cycle is at most 1 angstrom per cycle.
11. The method of any of the clauses 1-10, wherein process conditions (including at least one of temperature, oxygen and hydrogen exposure times, pressure, or purge times) and number of cycles are selected such that the III-V semiconductor surface has a roughness at most 0.13 nm over an area of 200 nm by 200 nm or the surface roughness is not increased by more than 10% as compared to before the etching.
12. A method, or the method of any of the clauses 1-11, comprising fabricating a high electron mobility transistor (HEMT) or other device comprising:
obtaining the III-V semiconductor layer comprising a channel layer; and
performing at least one gate recess etch on the III-V semiconductor layer (e.g., using the steps (a) and (b)) comprising sequential self-limiting half-cycles of the oxidizing agent exposure and the hydrogen radical exposure.
13. The method of clause 12, further comprising a wafer having a diameter of at least 3 inches comprising the semiconductor layer, the method comprising performing a plurality of gate recess etches across a surface area of the wafer to form a plurality of etched surfaces, wherein a roughness of each of the etched surfaces is uniform to within 10%.
14. A high electron mobility transistor (HEMT) device comprising:
an InGaAs layer channel layer;
an InAlAs barrier layer on the channel layer;
an InGaAs cap layer on the channel layer
a gate recess formed in the InGaAs cap layer exposing a surface of the InAlAs barrier layer or a surface of an InP etch stop layer on the barrier layer; wherein the surface gate recess has a surface roughness of at most 0.15 nm over the area of the gate recess.
15. The HEMT device of clause 14, comprising gate metal formed in the gate recess, wherein an interface region of the gate recess with the gate metal has a lower electrical trap density relative to the interface region when the gate recess is formed by wet chemical etching.
16. A wafer comprising a plurality of the HEMTs of clause 14 or 15, wherein the gate recesses have an etch depth precision and surface roughness that is uniform to within 5%.
17. The device or HEMT or wafer of any of the clauses fabricated using the method of any of the clauses 1-13.
18. A system or apparatus for atomic layer etching of a III-V semiconductor material, the system comprising:
an atomic layer etching apparatus or reactor coupled to a source of hydrogen radicals;
an angled conduit coupling the source of hydrogen radicals to the surface of a sample when mounted on a sample holder in the reactor, the angled conduit preventing direct line of sight between the source and the surface of the sample.
19 The apparatus of clause 18, further comprising computer programmable to
instruct output of the reactants performing a first half-cycle comprising exposing a surface of the III-V semiconductor material to an oxidizing agent to form an oxide layer on the surface; and
performing a second half-cycle comprising exposing the oxide layer to hydrogen radicals to remove the oxide layer from the surface to form an etched surface; wherein the first half-cycle and the second half-cycle are each self-limiting.
20 The system or apparatus of clause 18 or 19, wherein the source of hydrogen radicals comprises an inductively coupled plasma source or microwave plasma remotely coupled to a sample holder in the ALE reactor by the angled conduit, the reactor further comprising a reactor chamber comprising the sample holder; a pump for reducing pressure in the reactor chamber; and a heater and temperature sensor coupled to the sample holder for controlling a temperature of the sample holder.
21. The system or apparatus of clause 18 or 19, wherein the ALE reactor further comprises a reactor chamber comprising a sample holder and the source of hydrogen radicals comprises a filament and a source of hydrogen containing gas (e.g., H2) coupled to the reactor, wherein the filament is coupled to a power source for heating the filament to generate heat for thermal cracking to dissociate the hydrogen molecules in the reactor chamber, wherein the sample holder is further coupled to the source of hydrogen gas by the angled conduit, the system or apparatus further comprising a pump for reducing pressure in the reactor chamber; and the sample holder further coupled to a heater and temperature sensor for controlling a temperature of the sample holder.
22. The system or apparatus of any of the clauses 18-21 configured or operable to (including the computer programmable to or programmed to) implement the method of any of the clauses 1-13.
23. The system or apparatus of any of the clauses 18-22 configured or operable to (including the computer programmable to or programmed to) implement the method fabricating the device of any of the clauses 14-16.
24. The device or HEMT of any of the clauses 14-16 fabricated using the method of any of the clauses 1-13 or the system of any of the clauses 18-22.
25. A non-transitory computer readable medium comprising a computer program and/or operating instructions for executing or instructing the performance of any of the methods or functionalities of any of the clauses.
26. A non-transitory computer-readable medium storing instructions that, when executed by a processor, cause the apparatus or system of any of the clauses 18-23 to perform the methods or functionalities of any of the clauses 1-24.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The high frequency performance and yield of III-V semiconductor devices such as low-noise indium phosphide (InP) high-electron mobility transistor (HEMT) amplifiers is highly sensitive to subsurface etch damage and non-uniform etch depth over a wafer, particularly during the gate recess etch step. The industry standard method for gate recess etching of these devices is to employ a wet chemical acid-based etch, resulting in suboptimal damage and yield which in turn degrades device performance. Atomic layer etching (ALE) is able to overcome these challenges because of its ability to etch with Angstrom-scale precision, low damage, and intrinsic wafer-scale uniformity.

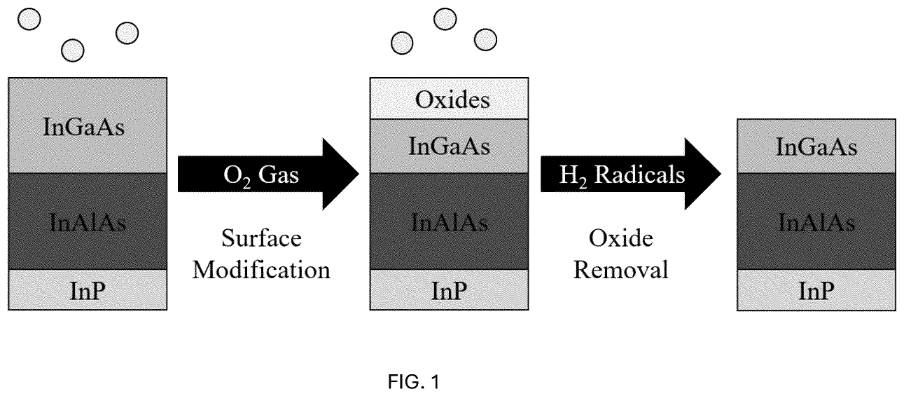

FIG. 1 illustrates a method of atomic layer etching of a III-V semiconductor material, comprising performing a first half-cycle comprising exposing a surface of the III-V semiconductor material to an oxidizing agent to form an oxide layer on the surface; and performing a second half-cycle comprising exposing the oxide layer to hydrogen radicals to remove the oxide layer from the surface; wherein the first half-cycle and the second half-cycle are each self-limiting.

### Experimental Results on Working Embodiment Applied to InGaAs

### 1. Samples and Methods

The samples consisted of an epitaxial stack of InGaAs and InAlAs films grown on an InP substrate by molecular beam epitaxy. The top film was a 200 nm thick lattice-matched n-In0.53Ga0.47As layer with carrier concentration of cm-3, below which was a 200 nm lattice matched In0.52Al0.48As buffer. The surface of InGaAs was found to be indium-rich via ex-situ x-ray photoelectron spectroscopy (XPS), as further discussed in table 1. The films were grown on 2-inch InP wafers and diced into mm² chips. Prior to use, the chips were spin cleaned with acetone followed by isopropyl alcohol at 4000 rpm.

ALE experiments were carried out in an Oxford Instruments FlexAL II atomic layer deposition tool. Hydrogen plasma was generated through an inductively coupled plasma (ICP) source. To limit ion damage to the chip, a pseudo-remote plasma was achieved by encasing the chip in a roof structure to eliminate the direct line of sight between the chip and the ICP plasma source. The roof structure was a mm2 sapphire chip supported by two mm2 sapphire chips, forming a channel in which the chip was placed. This structure allowed gas reactants to diffuse to the chip while minimizing direct ion impingement.

Thickness changes due to etching were measured by ex-situ ellipsometry using a J. A. Woolam M-2000 spectroscopic ellipsometer. Measurements were taken in the center of the chips in a line perpendicular to the channel of the roof structure with points spaced 1 mm apart to avoid edge effects from the roof structure. Chips were placed in the same position and orientation before and after etching. Ellipsometry data were taken between 370 and 1000 nm at angles of 60, 65, and 70 degrees. The data were fit using J. A. Woollam CompleteEASE software with a model consisting of InGaAs oxide, In0.53Ga0.47As, In0.52Al0.48As, and InP.

Before ALE, preconditioning of the chamber was performed to ensure a consistent initial chamber condition. The vacuum chamber chuck was heated to a processing temperature of 350 °C to allow it to thermalize while the rest of the preconditioning was carried out. Next, 6 min of Ar/O2/SF6 plasma (120 sccm Ar, 40 sccm SF6, 40 sccm O2) was performed, followed by 300 cycles of alumina ALD (nm). Alumina was chosen because it is resistant to the oxygen gas and hydrogen plasma used during ALE. Finally, 50 cycles of the ALE recipe was performed, after which the chip was loaded into the reactor.

The chip was then heated to 350 °C for 4 min while Ar was flowed at 100 sccm, with a chamber pressure of 100 m Torr. The ALE process was then carried out as shown in FIG. 1. First, 50 sccm of H2 flowed for 10 s, reaching a stable chamber pressure of 100 mTorr after which a plasma was struck at 100 W and held for 2 min. The chamber was then purged for 2 s with 200 sccm of Ar and then pumped down for 10 s. This initial 2 min H2 exposure was used to remove the oxide formed when the sample was removed from the chamber to perform ex-situ ellipsometry.

The main ALE cycle was then carried out as follows. The oxidation half-step was performed by flowing 100 sccm of O2 for 45 s, reaching a chamber pressure of 225 m Torr. The chamber was then purged by flowing 300 sccm of Ar for 3 s and then pumping down for 10 s. After this, the hydrogen plasma half-cycle was carried out by first flowing 50 sccm of H2 for 10 s at 100 m Torr and then striking and holding a 100 W plasma for 1 min. The chamber was then purged with Ar and then pumped down for 10 s before restarting the ALE cycle. After processing, the chamber was pumped down for 1 min before the chip was unloaded to the load-lock. The chip was then held in a dry nitrogen atmosphere in the load-lock for 5 min to cool.

The saturation curves were acquired at constant chamber temperature, pressure, and ICP plasma power, only varying the times of the oxygen gas and hydrogen radical exposures in their respective saturation curves while holding the other constant. The same purging and pumping procedure was used for all processes. The saturation curves were obtained using a single sample. After the chips were preconditioned, the initial film thicknesses were determined via ellipsometry. The chips then underwent 100 cycles of ALE for a given half cycle exposure time before being measured again by ellipsometry. This process was repeated to generate the saturation curve.

### 2. Characterization

Surface roughness measurements were taken using a Bruker dimension icon atomic force microscope (AFM). PeakForce tapping mode was used with a ScanAsyst-Air AFM probe. A nm2 square region was scanned by segmenting the region into 1024 lines, each of which contains 1024 points where data was collected. The raw height maps were processed using the NanoScope Analysis software from Bruker. This raw data was processed using a 2D flatten and low pass filter to remove tilt angle and scan artifacts. The power spectral density (PSD) was then calculated using Nanoscope's 2D isotropic PSD feature.

Surface characterization was performed via ex-situ XPS using a Kratos Axis Ultra XPS with a monochromatic Al Kα source. To perform depth profiling, an Ar ion beam, 4 keV with an extractor current of 140 μA, was used to raster a mm area in 30 s cycles, and data were collected for 8 subsurface points. The XPS data were processed using CASA-XPS from Casa Software Ltd. The backgrounds were taken to be Shirley and the line-shape of the In, Ga, and As peaks were taken to be a mix of Gaussian and Lorentzian. The exact ratio of the line-shape was determined by minimizing the residual of the individual peaks in the bulk where no oxide was present. To compare atomic percentages, the Scofield relative sensitivity factors were used, which recovered the expected In:Ga ratio of 1.13 in the bulk.

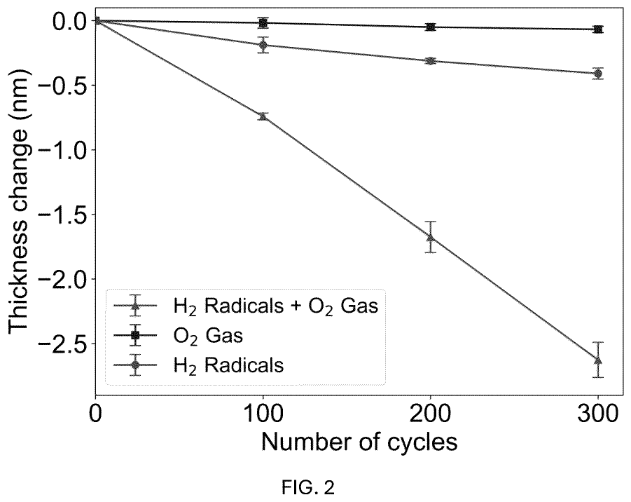

A comparison of the change in sample thickness with respect to cycle number for oxygen gas, hydrogen radicals, and both half steps is shown in FIG. 2. It is observed that the exposure of InGaAs to just oxygen gas has a negligible etch rate of 0.002 Å cycle-1. Exposure to only hydrogen radicals has a slightly higher EPC of 0.014 Å cycle-1. This EPC value can likely be attributed to the use of ex situ ellipsometry to measure the sample thickness, meaning that the sample was exposed to ambient air for some time prior to the measurement. As a result, some thickness of native oxide is formed which is then etched by the next hydrogen radical exposure. This etched thickness is included in the EPC for hydrogen radicals and thus results in a higher etch rate than the actual value. It is expected that the EPC excluding this effect is negligible.

Combining the two half cycles, an EPC of 0.095 Å cycle-1 is observed. The EPC was obtained by dividing the total thickness change after 300 cycles by the number of cycles. It is noted that to minimize process times, the sample was reused to obtain the thickness change after 100, 200, and 300 cycles, rather than using a new sample for each data point. This EPC is similar to the previously reported EPC of thermal ALE of InGaAs using HF and DMAC for which an etch rate of 0.10 Å cycle-1 at 250 °C was reported [25].

The chemistry for this etching has been extensively studied in the context of ultrahigh vacuum surface cleaning of III-V semiconductors using hydrogen radicals [28, 29]. The generally accepted reactions are:

$${As}_{2} {O}_{x} + 2 \times H \to x {H}_{2} O ↑ + {As}_{2} ( or \frac{1}{2} {As}_{4} ) ↑ \qquad ( 1 )$$

Ga₂O₃+4H→Ga₂O↑2H₂O↑ (2)

In₂O₃+4H→In₂O↑+2H₂O↑ (3)
where the up arrow indicates volatile species under vacuum. These reactions are all known to proceed with volatile products at temperatures above 200 °C. [28-31].

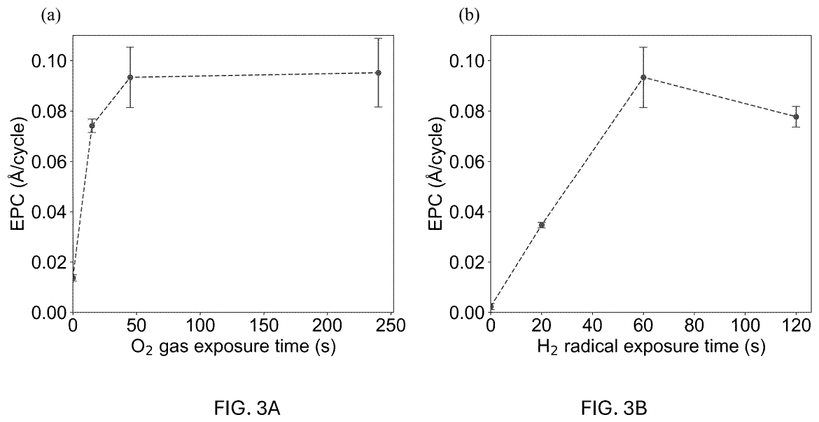

To gain further insight into the process, the saturation curves for both the hydrogen radical and oxygen gas half cycles were measured. FIG. 3(a) shows the O2 gas saturation curve. It is observed that the EPC increases with increasing O2 gas exposure time until an exposure of 45 s is reached, after which the EPC plateaus. It is concluded that the oxygen half cycle has reached saturation at a 45 s per cycle exposure. Next, FIG. 3(b) shows the H2 radical saturation curve. This plot likewise shows that increasing the hydrogen radical exposure time increases the EPC until 60 s after which it appears that the etch rate decreases slightly, although the EPC plateaus within uncertainty. This mild decrease could be due to H ion damage as the ion flux is non-negligible for sufficiently long exposures, despite the use of the roof structure. However, considering prior studies of hydrogen radicals with native oxides of InGaAs, saturation of the hydrogen radical step is expected. The saturated ALE conditions are taken to be 45 s of 02 and 60 s of H2 radicals for a process temperature of 350 °C.

The temperature dependence of the EPC was surveyed by running 200 cycles with saturated parameters obtained at 350 °C at 300 °C, 350 °C, and 400 °C. The EPC was found to increase by around 45% at a temperature of 400 °C and appeared to be negligible at 300 °C. It is expected that the EPC and its temperature dependence are primarily determined by the thickness of the oxidized layer. At room temperature, the oxygen uptake of oxygen gas on clean GaAs (110) surfaces has been extensively studied [32]. It is known that oxidation proceeds first by dissociative chemisorption followed by field-assisted growth (Cabrera-Mott mechanism). At room temperature, the transition between dissociative chemisorption and Cabrera-Mott begins at monolayers and requires an exposure of L. At elevated temperatures above C, dissociative chemisorption may be followed by parabolic growth corresponding to atomic diffusion of oxygen [33]. The increase in etch rate at 400 °C is therefore attributed to a combination of an increase in the dissociative chemisorption rate constant (Arrhenius behavior) and also an increase in the thermal diffusivity of oxygen (parabolic behavior).

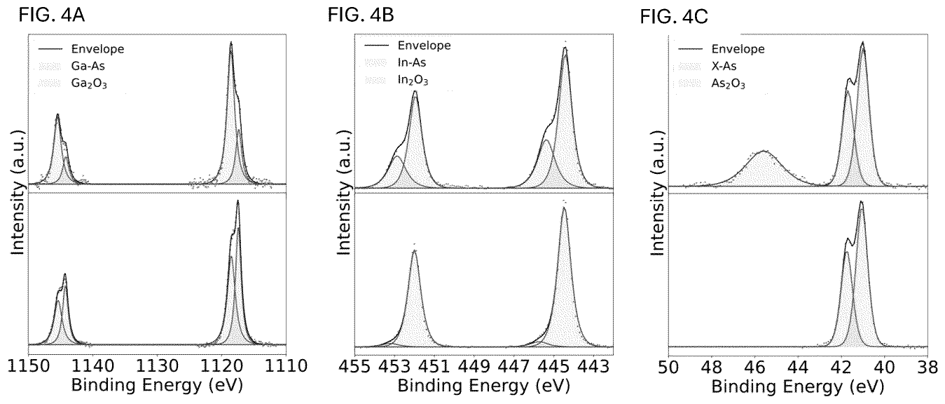

The surface chemical composition of the InGaAs samples before and after ALE was analyzed using ex-situ XPS. FIG. 4 shows the core level spectra for In3d, As3d, and Ga2p before and after 200 cycles of ALE. It is observed that the In and Ga core level spectra have two doublet peaks. There are two peaks due to the spin orbital splitting of these levels, 3d5/2 and 3d3/2 for In and 2p1/2, 2p3/2 for Ga, and they are doublets due to the fact that these metals have two distinct chemical bonding environments: one metallic and one involving bonding with oxygen. The higher energy peak in the doublet corresponds to the oxides. The As peak doublet is due to spin orbital splitting (3d5/2 and 3d3/2), and the second peak corresponds to bonding with oxygen.

Qualitatively, it is seen that there are relatively fewer surface oxides after ALE despite the samples being exposed to ambient air prior to XPS. The proportion of indium oxide on the surface has also decreased relative to gallium oxide, and there is no detectable As oxide on the surface after ALE. A prior study of InGaAs oxide etching using hydrogen radicals did not detect any oxide signal using in-situ XPS [34], and therefore the gallium oxide surface signal in FIG. 4 is attributed to atmospheric exposure after leaving the etching chamber.

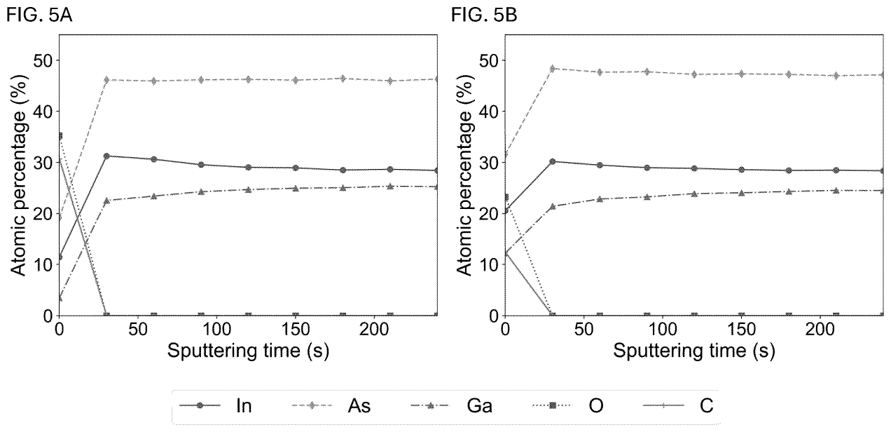

To assess the degree to which the processing is confined to the surface region, XPS depth profiling was performed. The atomic concentrations of O, C, In, Ga, and As with respect to milling time for both the original sample and a sample etched with 200 cycles of ALE are shown in FIG. 5. The bulk atomic composition after ALE was observed to differ from that of the original sample by at most 3%. Furthermore, the bulk ratio of In:Ga was around 1.13, the expected value from the specified alloy composition of In0.53Ga0.47As.

The surface composition of both the original and the ALE sample is shown in table 1. It is observed that after ALE the surface atomic concentration of oxygen decreases by 34.0%. It was also observed that the ratio of In:Ga was halved after ALE. However, the In:Ga ratio after ALE, 1.7, is still above the bulk ratio of 1.13. It should be noted that the original sample surface was In-rich compared to the bulk composition (cf table 1). It is unclear if this apparent decrease in In from ALE indicates preferential etching or the gradient in In composition towards the bulk value in the sample. A previous study of thermal ALE of InGaAs noted preferential etching of In over Ga, which ultimately led to termination of the etch [25]. In the present case, even if preferential etching occurs, etch termination is not expected as H radicals also etch the oxides of GaAs [35].

TABLE 1
Surface atomic composition in atomic percentage from XPS.

| | In (%) | As (%) | Ga (%) | O (%) | C (%) |
|---|---|---|---|---|---|
| Original | 11.43 ± 0.07 | 19.16 ± 0.27 | 3.45 ± | 35.26 ± | 30.70 ± |
| | | | 0.06 | 1.34 | 2.41 |
| ALE | 20.57 ± 0.08 | 31.56 ± 0.35 | 12.21 ± | 23.26 ± | 12.41 ± |
| | | | 0.22 | 2.85 | 1.22 |

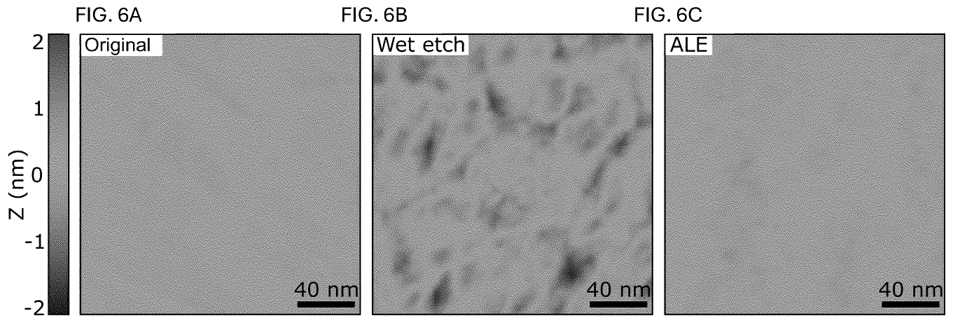

AFM was used to characterize the surface roughness of an original InGaAs sample with its native oxide, a sample subjected to 200 cycles of ALE (etch depth of 2 nm), and a sample etched for ~5 s (etch depth of nm) with a citric acid/H2O2 wet etch, which is commonly used for gate recess etching. FIG. 6 shows a height map of the surface of these samples. The original sample (FIG. 6(a)) has a nm, as expected for an epitaxially grown film. The wet etched sample (FIG. 6(b)) is visibly rougher with nm. The ALE sample (FIG. 6(c)) has nm which is indistinguishable from that of the MBE-grown sample.

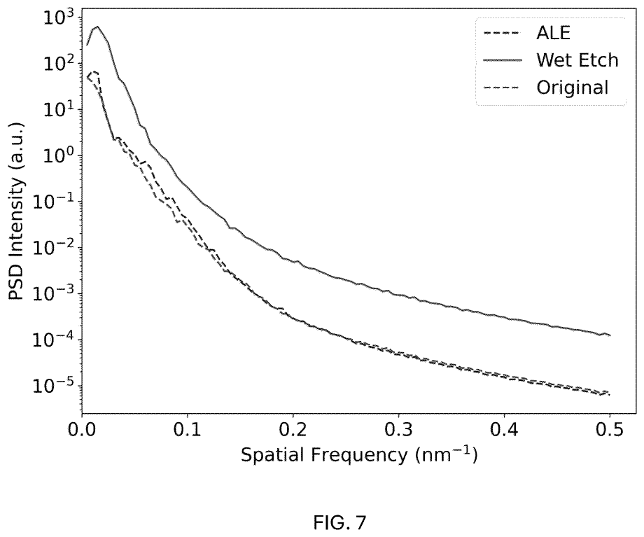

PSD is another way to quantify surface roughness over characteristic length scales as quantified by the spatial frequency. The PSD of the AFM scans is shown in FIG. 7. It is observed that the wet-etched sample has a higher PSD over all spatial frequencies compared to the original sample. On the other hand, the ALE sample exhibits a PSD which nearly coincides with that of the original sample. This result further confirms that 200 cycles of ALE does not increase the surface roughness.

### 3. Comparison to Other Methods

Conventional InGaAs ALE processes are discussed in relation to the present process and their respective advantages. An early ALE process employed chlorine plasma and low energy Ar ions [27]. This process can be performed down to room temperature and is directional, but it may damage the surface due to the energetic plasma and can exhibit redeposition of involatile In chlorides. A thermal ALE process consisting of HF and DMAC exposures provides sub-Angstrom EPC, sub-nanometer surface smoothness, and imparts no physical surface damage due to the absence of plasma [26]. However, the etch appears to terminate after several hundred cycles due to preferential etching of In compounds. The present process is most similar to the thermal ALE process in that it exhibits sub-Angstrom EPC and low damage due to the use of thermal reactants.

### 4. Possible Modifications and Variations

An intermediate process employing remote oxygen plasma or ozone may be feasible to increase EPC and reduce saturation time while maintaining the low-damage characteristics. This would be greatly aided by in situ ellipsometry, as thickness changes of both the InGaAs film and its oxide layer may be observed in real time. This would allow not only for the measurement of etch rates and saturation curves without exposing samples to ambient conditions, but also insight into the mechanism of oxidation at the process conditions. A downstream plasma or thermal source of hydrogen radicals could be used to eliminate ion damage while also providing a higher radical density. If the roof structure can be eliminated, the etch rate with oxygen gas is expected to approach a monolayer per cycle corresponding to the expected thickness of the oxidized layer. Finally, surface passivation schemes for the exposed InAlAs can also be implemented. ALE offers the possibility for in-situ passivation of this surface in the clean environment of high vacuum, potentially via formation of a crystalline oxide followed by atomic layer deposition [36], or other schemes.

### 5. Example Applications

The ALE process described herein has potential applications for III-V compound semiconductor devices by enabling precise etch control on the Angstrom scale with wafer-scale uniformity. Unlike continuous wet or dry etching processes which are subject to local variations in etch rate over a wafer, ALE is inherently scalable to arbitrary wafer sizes owing to the use of self-limiting surface chemical reactions. This process may find application as gate recess etching for InP HEMTs where sub-nanometer precision in the etch depth over a 3″ or larger InP wafer is desired for optimal yield. The low surface damage of ALE compared to traditional wet or dry etches may facilitate more aggressive device scaling, leading to improved high frequency performance. A lower electrical trap density on the ALE-treated surface is also expected, which could lead to improved gain stability.

### Process Steps

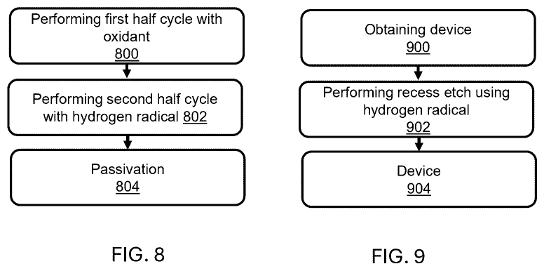

FIG. 8 is a flowchart illustrating a method of atomic layer etching of a III-V semiconductor material (where III and V represent group III and group V of the periodic table, respectively). Examples of III-V semiconductor material include at least one of InGaAs, InAlAs, or InP. Other examples include III-Nitride materials such as GaN, AlGaN, InGaN etc. The method comprises the following steps.

Block 800 represents performing a first half-cycle comprising exposing a surface of the III-V semiconductor material to an oxidizing agent to form an oxide layer on the surface. Examples of III-V semiconductor material include at least one of InGaAs, InAlAs, or InP. Other examples include III-Nitride materials such as GaN, AlGaN, InGaN etc. Examples of oxidizing agent include at least one of oxygen gas, ozone, or remote oxygen plasma.

Block 802 represents performing a second half-cycle comprising exposing the oxide layer to hydrogen radicals to remove the oxide layer from the surface to form an etched surface; e.g., wherein the first half-cycle and the second half-cycle are each self-limiting. Examples of a hydrogen plasma comprising the hydrogen radicals, one or more hydrogen (H) atoms, or neutral dissociated H2 (hydrogen by itself). In some embodiments, and without being bound by a particular scientific theory, the advantage of hydrogen is that it does not introduce undesirable species into the etched surface.

Block 804 depositing a passivation layer on the etched surface, or passivating the etched surface, using atomic layer deposition (ALD) in situ in the same reactor with the atomic layer etching. In one or more embodiments, the wherein the passivation layer comprises a high k dielectric layer where k is at least 9 (e.g., alumina, hafnia, HfO2, or titanium dioxide, k 9, 15-20). In some embodiments, the passivation layer is 1 nm thick, for example, or otherwise terminates dangling bonds, e.g., to suppress degradation in environment outside the reactor. In some embodiments, the etched surface on which passivation is performed is InP, which is easier to passivate than InGaAs.

In one or more embodiments, the hydrogen radicals are generated by an inductively coupled plasma source operated in a pseudo-remote plasma configuration that reduces direct ion impingement on the III-V semiconductor surface, thermal cracking with a hot filament, or a microwave plasma source.

Example implementations of the method include, but are not limited to:
1. The method of any of the embodiments wherein the etch per cycle is at most 1 angstrom per cycle.
2. The method of any of the embodiments wherein process conditions (including at least one of temperature, oxygen and hydrogen exposure times, pressure, or purge times) and number of cycles are selected such that the III-V semiconductor surface has a roughness at most 0.13 nm over an area of 200 nm by 200 nm or the surface roughness is not increased by more than 10% as compared to before the etching.
3. The method of any of the embodiments further comprising depositing a passivation layer on the etched surface, or passivating the etched surface, using atomic layer deposition in situ with the atomic layer etching.
4. The method of any of the embodiments wherein the passivation layer comprises a high k dielectric layer where k is at least 9 or in a range of 15-20.
5. The method of any of the embodiments wherein the III-V semiconductor material comprises at least one of InGaAs, InAlAs, or InP.
6. The method of any of the embodiments wherein the oxidizing agent is at least one of oxygen gas, ozone, or remote oxygen plasma.
7. The method of any of the embodiments further comprising a hydrogen plasma comprising the hydrogen radicals.
8. The method of any of the embodiments, wherein the hydrogen radicals consist essentially of, consist of, or are hydrogen atoms or dissociated neutral hydrogen molecules.
9. The method of any of the embodiments performed at a process temperature between about 200 degrees Celsius and about 400 degrees Celsius. The temperature may vary depending on the semiconductor material. For example, etching InP may use temperatures at the higher end of the range.

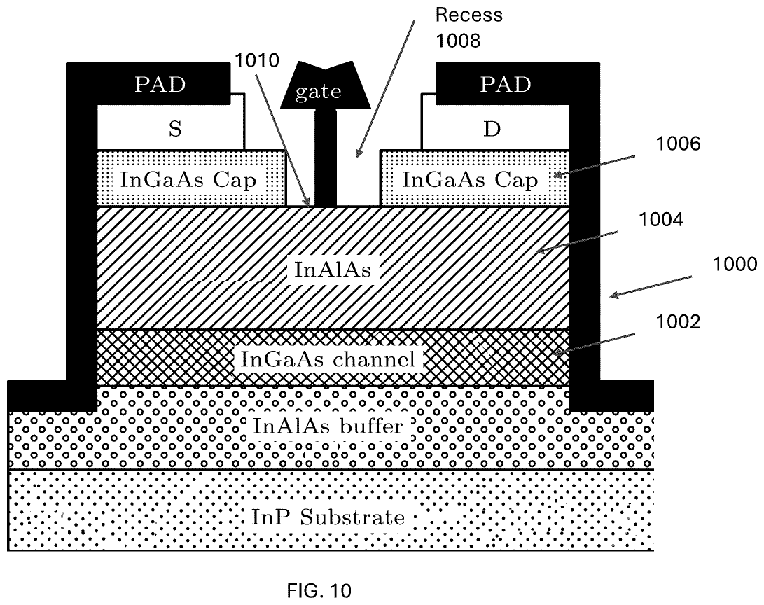

FIG. 9 is a flowchart illustrating a method of fabricating a transistor, e.g., high electron mobility transistor (HEMT) comprising the following steps.

Block 900 represents obtaining a III-V semiconductor layer comprising a channel layer.

Block 902 represents performing at least one gate recess etch on the III-V semiconductor layer, wherein the gate recess etch includes atomic layer etching comprising sequential self-limiting half-cycles of an oxidizing agent exposure and hydrogen radical exposure.

Block 904 represents the end result, a device or wafer.

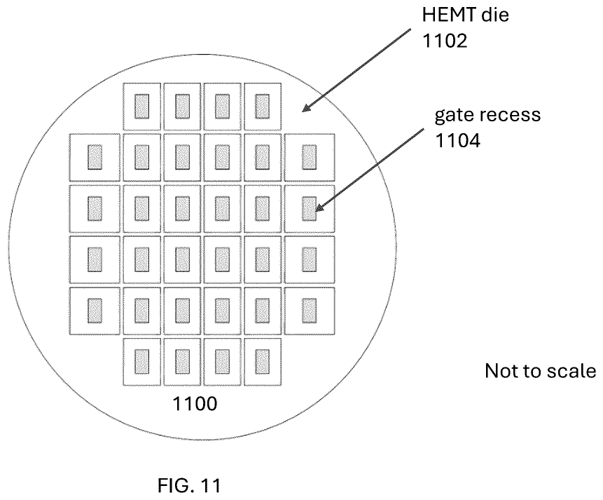

FIG. 10 illustrates an example of a device comprising a high electron mobility transistor (HEMT) device 1000 comprising an InGaAs layer channel layer 1002; an InAlAs barrier layer 1004 on the channel layer; an InGaAs cap layer 1006 on the channel layer; optional InP etch stop between the InGaAs cap layer and InAlAs barrier layer; a gate recess 1008 formed in the InGaAs cap layer exposing a surface 1010 of the InAlAs barrier layer (or optionally a surface of an InP etch stop layer on the barrier layer); wherein the surface gate recess has a surface roughness of at most 0.15 nm over the area of the gate recess. In one or more embodiments, gate metal formed in the gate recess, wherein an interface region of the gate recess with the gate metal has a lower electrical trap density relative to the interface region when the gate recess is formed by wet chemical etching. The barrier layer can confine a two dimensional electron gas or two dimensional hole gas in the channel layer. Other devices or transistors can be fabricated using the method. Gate in recess 1008 and source(S) and drain (D) and contact pads also shown.

In one or more embodiments, the process is performed on a wafer having a diameter of at least 3 inches comprising the semiconductor layer, the method comprising performing a plurality of gate recess etches across a surface area of the wafer to form a plurality of etched surfaces, wherein a roughness of each of the etched surfaces is uniform to within 10%. As discussed herein, examples of the III-V semiconductor include at least one of Indium Gallium Arsenide (InGaAs), Indium Aluminum Arsenide (InAlAs), or Indium Phosphide (InP), or III-Nitride materials.

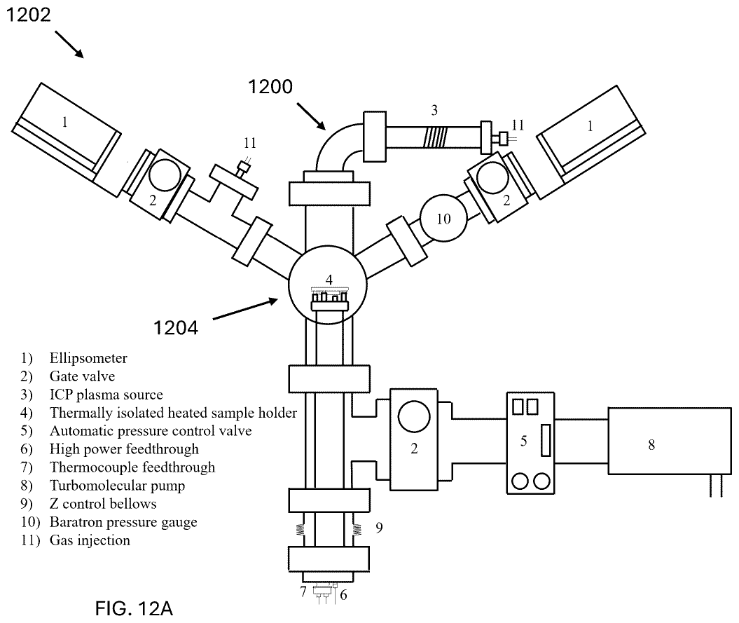

FIG. 11 illustrates a wafer 1100 comprising a plurality of the HEMTs 1102 wherein the gate recesses 1104 have an etch depth precision and surface roughness that is uniform to within 5%.

### Example Apparatus

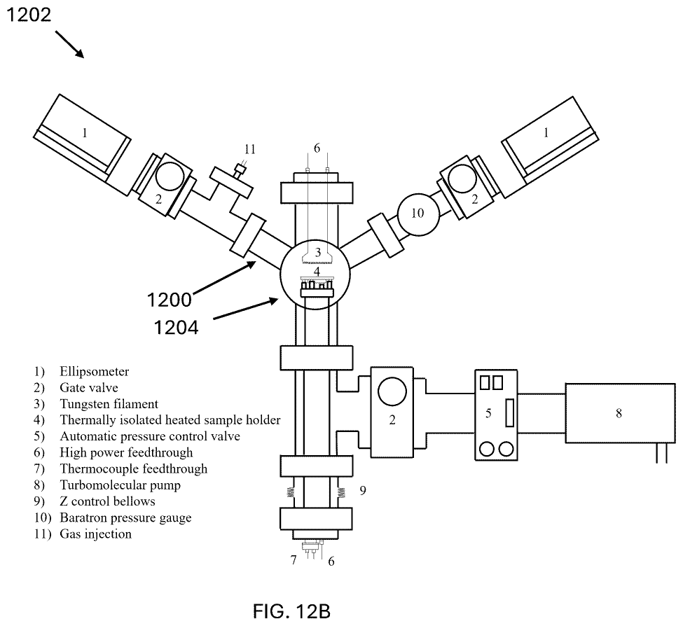

FIGS. 12A and 12B illustrates a system for atomic layer etching (ALE) of a III-V semiconductor material, the system comprising an atomic layer etching apparatus or reactor coupled to a source (3) of hydrogen radicals; an angled conduit 1200 (e.g., but not limited to, a pipe, tubing, e.g. comprising metal and/or teflon) coupling the source of hydrogen radicals to the surface of sample when mounted on a sample holder 4 in the reactor, the angled conduit preventing direct line of sight between the source and the surface of the sample. The inner surface of the angled conduit can be coated a material that prevents loss of absorption of the hydrogen radicals in the conduit, e.g., a Teflon coating. The angled conduit can include a bend of at least 45 degrees, for example.

The system further comprises a source for the oxidizing agent a source for the hydrogen radicals. The source for the hydrogen radicals may comprise an inductively coupled plasma source operated in a pseudo-remote plasma configuration that reduces direction impingement on the III-V semiconductor surface, thermal cracking with a hot filament, or a microwave plasma source

The reactor can comprise one or more reactor tools for reacting a reactant with a surface of the III-V semiconductor to perform the etching and or deposition (passivation) steps described herein. The reactor can comprise or be coupled to a computer programmable to instruct output of the reactants performing a first half-cycle comprising exposing a surface of the III-V semiconductor material to an oxidizing agent to form an oxide layer on the surface; and performing a second half-cycle comprising exposing the oxide layer to hydrogen radicals to remove the oxide layer from the surface to form an etched surface; wherein the first half-cycle and the second half-cycle are each self-limiting.

The reactor can comprise an ALE reactor, or a joint ALE/ALD reactor.

FIG. 12A is a schematic diagram of an atomic layer etching (ALE) system according to one embodiment comprising the following labeled components: two ellipsometers (1), gate valves (2), an ICP plasma source (3), a thermally isolated heated sample holder (4), an automatic pressure control valve (5), a high power feedthrough (6), a thermocouple feedthrough (7), a turbomolecular pump (8), Z control bellows (9), a Baratron pressure gauge (10), and gas injection ports (11).

In one or more embodiments, the ICP plasma source for the hydrogen radicals can be replaced with a microwave plasma source.

FIG. 12B is a schematic diagram of an ALE system according to another embodiment using thermal cracking (using a hot filament) for the source of hydrogen radicals. The system comprises the following labeled components: two ellipsometers (1), gate valves (2), a tungsten filament (3), a thermally isolated heated sample holder (4), an automatic pressure control valve (5), a high power feedthrough (6), a thermocouple feedthrough (7), a turbomolecular pump (8), Z control bellows (9), a Baratron pressure gauge (10), and gas injection ports (11).

Both embodiments illustrated in FIGS. 12A and 12B can be used for atomic layer deposition of the passivation layer.

The system or apparatus can be configured or operable to (including the computer programmable to or programmed to) implement any of the methods disclosed herein, including those in FIGS. 8-9. The system or apparatus can be configured or operable to (including the computer programmable to or programmed to) implement the method fabricating any of the devices disclosed herein.

FIG. 12A Illustrates a reactor 1202 wherein the source of hydrogen radicals comprises an inductively coupled plasma source 3 or microwave plasma remotely coupled to a sample holder 4 in the ALE reactor by the angled conduit 1200, the reactor further comprising a reactor 1204 chamber comprising the sample holder; a pump 8 for reducing pressure in the reactor chamber; and a heater and temperature sensor coupled to the sample holder for controlling a temperature of the sample holder.

FIG. 12B illustrates an example wherein the ALE reactor 1202 further comprises a reactor chamber 1204 comprising a sample holder 4 and the source of hydrogen radicals comprises a filament 3 and a source or inlet 11 for a source of hydrogen containing gas (e.g., H₂) coupled to the reactor, wherein the filament is coupled to a power source for heating the filament to generate heat for thermal cracking to dissociate the hydrogen molecules in the reactor chamber, wherein the sample holder is further coupled to the source of hydrogen gas by the angled conduit, the system or apparatus further comprising a pump for reducing pressure in the reactor chamber; and the sample holder further coupled to a heater and temperature sensor for controlling a temperature of the sample holder.

### Hardware Environment

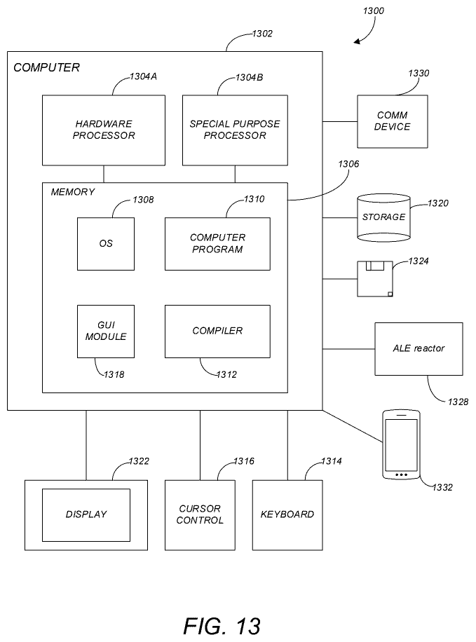

FIG. 13 is an exemplary hardware and software environment 900 (referred to as a computer-implemented system and/or computer-implemented method) coupled to ALE reactor (or ALD/ALE reactor/apparatus) 1328 used to implement one or more embodiments of the invention for performing ALE and optionally atomic layer deposition (ALD). The hardware and software environment includes a computer 1302 and may include peripherals. Computer 1302 may be a user/client computer, server computer, or may be a database computer. The computer 1302 comprises a hardware processor 1304A and/or a special purpose hardware processor 1304B (hereinafter alternatively collectively referred to as processor 1304) and a memory 1306, such as random access memory (RAM). The computer 1302 may be coupled to, and/or integrated with, other devices, including input/output (I/O) devices such as a keyboard 1314, a cursor control device 1316. In one or more embodiments, computer 1302 may be coupled to, or may comprise, a portable or multi-touch device, e.g., mobile phone or laptop, or other device executing on various platforms and operating systems.

In one embodiment, the computer 1302 operates by the hardware processor 1304A performing instructions defined by the computer program 1310 under control of an operating system 1308. The computer program 1310 and/or the operating system 1308 may be stored in the memory 1306 and may interface with the user and/or other devices to accept input and commands and, based on such input and commands and the instructions defined by the computer program 1310 and operating system 1308, to provide output and results.

Output/results may be presented on the display 1322 or provided to another device for presentation or further processing or action. The image may be provided through a graphical user interface (GUI) module 1318. Although the GUI module 1318 is depicted as a separate module, the instructions performing the GUI functions can be resident or distributed in the operating system 1308, the computer program 1310, or implemented with special purpose memory and processors.

Some or all of the operations performed by the computer 1302 according to the computer program 1310 instructions may be implemented in a special purpose processor 1304B. In this embodiment, some or all of the computer program 1310 instructions may be implemented via firmware instructions stored in a read only memory (ROM), a programmable read only memory (PROM) or flash memory within the special purpose processor 1304B or in memory 1306. The special purpose processor 1304B may also be hardwired through circuit design to perform some or all of the operations to implement the present invention. Further, the special purpose processor 1304B may be a hybrid processor, which includes dedicated circuitry for performing a subset of functions, and other circuits for performing more general functions such as responding to computer program 1310 instructions. In one embodiment, the special purpose processor 1304B is an application specific integrated circuit (ASIC), field programmable gate array, graphics processing unit, neural processing unit or processor, accelerator or circuit adapted for performing machine learning or artificial intelligence.

The computer 1302 may also implement a compiler 1312 that allows an application or computer program 1310 written in a programming language such as C, C++, Assembly, SQL, PYTHON, PROLOG, MATLAB, RUBY, RAILS, HASKELL, or other language to be translated into processor 1304 readable code. Alternatively, the compiler 1312 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 1310 accesses and manipulates data accepted from I/O devices and stored in the memory 1306 of the computer 1302 using the relationships and logic that were generated using the compiler 1312.

The computer 1302 also optionally comprises an external communication device such as a modem, satellite link, Ethernet card, or other device for accepting input from, and providing output to, other computers 1302.

In one embodiment, instructions implementing the operating system 1308, the computer program 1310, and the compiler 1312 are tangibly embodied in a non-transitory computer-readable medium, e.g., data storage device 1320, which could include one or more fixed or removable data storage devices, such as a zip drive, floppy disc drive 1324, hard drive, CD-ROM drive, tape drive, etc. Further, the operating system 1308 and the computer program 1310 are comprised of computer program 1310 instructions which, when accessed, read and executed by the computer 1302, cause the computer 1302 to perform the steps necessary to implement and/or use the present invention or to load the program of instructions into a memory 1306, thus creating a special purpose data structure causing the computer 1302 to operate as a specially programmed computer executing the method steps described herein. Computer program 1310 and/or operating instructions may also be tangibly embodied in memory 1306 and/or data communications devices 1330, thereby making a computer program product or article of manufacture according to the invention. As such, the terms “article of manufacture,” “program storage device,” and “computer program product,” as used herein, are intended to encompass a computer program accessible from any computer readable device or media. Of course, those skilled in the art will recognize that any combination of the above components, or any number of different components, peripherals, and other devices, may be used with the computer 1302.

### Advantages and Improvements

The high frequency performance and yield of III-V semiconductor devices such as low-noise indium phosphide (InP) high-electron mobility transistor (HEMT) amplifiers is highly sensitive to subsurface etch damage and non-uniform etch depth over a wafer, particularly during the gate recess etch step. The industry standard method for gate recess etching of these devices is to employ a wet chemical acid-based etch, resulting in suboptimal damage and yield which in turn degrades device performance. Atomic layer etching (ALE) is able to overcome these challenges because of its ability to etch with Angstrom-scale precision, low damage, and intrinsic wafer-scale uniformity.

The high frequency performance and yield of III-V semiconductor devices such as InP high electron mobility transistors (HEMTs) is negatively impacted by subsurface etch damage and non-uniform etch depth over the wafer. Atomic layer etching (ALE) has the potential to overcome this challenge due to its ability to etch with Angstrom-scale precision, low damage, and intrinsic wafer-scale uniformity. An ALE process for InGaAs based on sequential atomic hydrogen and oxygen gas exposures is reported herein.

### REFERENCES

The following references are incorporated by reference herein:
[1] Deal W R and Chattopadhyay G 2012 InP HEMT integrated circuits for Submillimeter Wave radiometers in earth remote sensing 2012 IEEE/MTT-S Int. Microwave Symp. Digest (Montreal, QC, Canada) (IEEE) pp 1-3
[2] Marian W P 2018 Extremely low-noise cryogenic amplifiers for radio astronomy: past, present and future 2018 22nd Int. Microwave and Radar Conf. (MIKON) (IEEE) pp 1-6
[3] Chiong C-C, Wang Y, Chang K-C and Wang H 2022 Low-noise amplifier for next-generation radio astronomy telescopes: review of the state-of-the-art cryogenic LNAs in the most challenging applications IEEE Microw. Mag. 23 31-47
[4] Alt A R, Bolognesi C R, Gallego J D, Diez C, Lopez-Fernandez I and Barcia A 2011 Ultra-low noise inp phemts for cryogenic deep-space and radio-astronomy applications IPRM 2011-23rd Int. Conf. on Indium Phosphide and Related Materials pp 1-4
[5] Hamada H, Tsutsumi T, Sugiyama H, Matsuzaki H, Song H-J, Itami G, Fujimura T, Abdo I, Okada K and Nosaka H 2019 Millimeter-wave InP device technologies for ultra-high speed wireless communications toward beyond 5G 2019 IEEE Int. Electron Devices Meeting (IEDM) p 9.2.1-9.2.4
[6] Park W-S 2023 Sub-50 nm terahertz In0.8 Ga0.2 as quantum-well high-electron-mobility transistors for 6G applications IEEE Trans. Electron Devices 70 2081-9
[7] J C Bardin 2021 Cryogenic low-noise amplifiers: noise performance and power dissipation IEEE Solid-State Circuits Mag. 13 22-35
[8] Bardin J C, Slichter D H and Reilly D J 2021 Microwaves in quantum computing IEEE J. Microw. 1 403-27
[9] Li J, Bergsten J, Pourkabirian A and Grahn J 2024 Investigation of noise properties in the InP HEMT for LNAs in Qubit amplification: effects from channel indium content IEEE J. Electron Devices Soc. 12 243-8
[10] Leuther A et al 2009 Metamorphic HEMT technology for low-noise applications 2009 IEEE Int. Conf. on Indium Phosphide & Related Materials pp 188-91
[11] Heinz F, Thome F, Leuther A and Ambacher O 2021 A 50-nm gate-length metamorphic HEMT technology optimized for cryogenic ultra-low-noise operation IEEE Trans. Microw. Theory Tech. 69 3896-907
[12] Saranovac T, Hambitzer A, Ruiz D C, Ostinelli O and Bolognesi C R 2017 Pt gate sink-in process details impact on InP HEMT DC and RF performance IEEE Trans. Semicond. Manuf. 30 462-7
[13] Li J, Pourkabirian A, Bergsten J, Wadefalk N and Grahn J 2022 Influence of spacer thickness on the noise performance in InP HEMTs for cryogenic LNAs IEEE Electron Device Lett. 43 1029-32
[14] Yun D-Y, Jo H-B, Son S-W, Baek J-M, Lee J-H, Kim T-W, Kim D-H, Tsutsumi T, Sugiyama H and Matsuzaki H 2018 Impact of the source-to-drain spacing on the DC and RF characteristics of InGaAs/InAlAs high-electron mobility transistors IEEE Electron Device Lett. 39 1844-7
[15] Christensson S, Lundström I and Svensson C 1968 Low frequency noise in MOS transistors-I theory Solid-State Electron. 11 797-812
[16] van der Ziel A 1988 Unified presentation of 1/f noise in electron devices: fundamental 1/f noise sources Proc. IEEE 76 233-58
[17] Weinreb S and Schleeh J 2014 Multiplicative and additive low-frequency noise in microwave transistors IEEE Trans. Microw. Theory Tech. 62 83-91
[18] Kanarik K J, Tan S and Gottscho R A 2018 Atomic layer etching: rethinking the art of etch J. Phys. Chem. Lett. 9 4814-21
[19] Sakaue H, Iseda S, Asami K, Yamamoto J, Hirose M and Horiike Y 1990 Atomic layer controlled digital etching of silicon Jpn. J. Appl. Phys. 29 2648
[20] Park S D, Oh C K, Lim W S, Lee H C, Bae J W, Yeom G Y, Kim T W, Song J I and Jang J H 2007 Highly selective and low damage atomic layer etching of InP/InAlAs heterostructures for high electron mobility transistor fabrication Appl. Phys. Lett. 91 013110
[21] Kim T-W, Song J-I, Jang J H, Kim D-H, Park S D, Bae J W and Yeom G Y 2007 Fabrication of InAs composite channel high electron mobility transistors by utilizing Ne-based atomic layer etching Appl. Phys. Lett. 91 102110
[22] Kim T-W et al 2008 A two-step-recess process based on atomic-layer etching for high-performance In0.52Al0.48As/In0.53Ga0.47As p-HEMTs IEEE Trans. Electron Devices 55 1577-84
[23] Lee Y, DuMont J W and George S M 2015 Atomic layer etching of AlF3 using sequential, self-limiting thermal reactions with Sn(acac)2 and hydrogen fluoride J. Phys. Chem. C 119 25385-93
[24] Zywotko D R and George S M 2017 Thermal atomic layer etching of ZnO by a ‘Conversion-Etch’ mechanism using sequential exposures of hydrogen fluoride and trimethylaluminum Chem. Mater. 29 1183-91
[25] Lu W, Lee Y, Gertsch J C, Murdzek J A, Cavanagh A S, Kong L, del Alamo J A and George S M 2019 In situ thermal atomic layer etching for sub-5 nm InGaAs multigate MOSFETs Nano Lett. 19 5159-66
[26] Wenjie L, Lee Y, Murdzek J, Gertsch J, Vardi A, Kong L, George S M and del Alamo JA 2018 First transistor demonstration of thermal atomic layer etching: InGaAs FinFETs with sub-5 nm fin-width featuring in situ ALE-ALD 2018 IEEE Int. Electron Devices Meeting (IEDM) p 39.1.1-39.1.4
[27] Park J W, Kim D S, Mun M K, Lee W O, Kim K S and Yeom G Y 2017 Atomic layer etching of InGaAs by controlled ion beam J. Phys. D: Appl. Phys. 50 254007
[28] Razek N, Otte K, Chasse T, Hirsch D, Schindler A, Frost F and Rauschenbach B 2002 Gaas surface cleaning by low energy hydrogen ion beam treatment J. Vac. Sci. Technol. A 20 1492-7
[29] Aguirre-Tostado F S, Milojevic M, Hinkle C L, Vogel E M, Wallace R M, McDonnell S and Hughes G J 2008 Indium stability on InGaAs during atomic H surface cleaning Appl. Phys. Lett. 92 171906
[30] Akatsu T, Plössl A, Scholz R, Stenzel H and Gösele U 2001 Wafer bonding of different III-V compound semiconductors by atomic hydrogen surface cleaning J. Appl. Phys. 90 3856-62
[31] Holloway P H and McGuire G E 1995 Handbook of Compound Semiconductors: Growth, Processing, Characterization and Devices (Noyes Publications)
[32] Mönch W 1986 On the oxidation of III-V compound semiconductors Surf. Sci. 168 577-93
[33] Butcher D N and Sealy B J 1978 The thermal oxidation of GaAs J. Phys. D: Appl. Phys. 11 1451
[34] Lau W M, Sodhi R N S, Jin S, Ingrey S, Puetz N and SpringThorpe A 1990 Capping and decapping of InP and InGaAs surfaces J. Appl. Phys. 67 768-73
[35] Petit E J and Houzay F 1994 Optimal surface cleaning of GaAs (001) with atomic hydrogen J. Vac. Sci. Technol. B 12 547-50
[36] Qin X, Wang W-E, Droopad R, Rodder M S and Wallace R M 2017 A crystalline oxide passivation on In0.53Ga0.47As (100) J. Appl. Phys. 121 125302
[37] Further information on one or more embodiments can be found in Atomic layer etching of InGaAs using sequential exposures of atomic hydrogen and oxygen gas, Mete M Bayrak, Anthony J Ardizzi, Sadhvikas Addamane, Kieran A Cleary and Austin J Minnich*Published 13 Nov. 2025 •Semiconductor Science and Technology, Volume 40, Number 11, Mete M Bayrak et al 2025 Semicond. Sci. Technol. 40 115012DOI 10.1088/1361-6641/ae16cb.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of atomic layer etching of a III-V semiconductor material, comprising:
(a) performing a first half-cycle comprising exposing a surface of the III-V semiconductor material to an oxidizing agent to form an oxide layer on the surface; and
(b) performing a second half-cycle comprising exposing the oxide layer to hydrogen radicals to remove the oxide layer from the surface to form an etched surface; wherein the first half-cycle and the second half-cycle are each self-limiting.

2. The method of claim 1, further comprising depositing a passivation layer on the etched surface, or passivating the etched surface, using atomic layer deposition in situ with the atomic layer etching.

3. The method of claim 2, wherein the passivation layer comprises a high k dielectric layer where k is at least 9.

4. The method of claim 1, wherein the III-V semiconductor material comprises at least one of InGaAs, InAlAs, or InP.

5. The method of claim 1, wherein the oxidizing agent is at least one of oxygen gas, ozone, or remote oxygen plasma.

6. The method of claim 1, further comprising a hydrogen plasma comprising the hydrogen radicals.

7. The method of claim 1, wherein the hydrogen radicals consist essentially of hydrogen atoms or dissociated neutral hydrogen molecules.

8. The method of claim 1, wherein the hydrogen radicals are generated by:
an inductively coupled plasma source operated in a pseudo-remote plasma configuration that reduces direct ion impingement on the III-V semiconductor surface,
thermal cracking with a hot filament, or
a microwave plasma source

9. The method of claim 1, wherein the method is performed at a process temperature between about 200 degrees Celsius and about 400 degrees Celsius.

10. The method of claim 1, wherein the etch per cycle is at most 1 angstrom per cycle.

11. The method of claim 1, wherein process conditions (including at least one of temperature, oxygen and hydrogen exposure times, pressure, or purge times) and number of cycles are selected such that the III-V semiconductor surface has a roughness at most 0.13 nm over an area of 200 nm by 200 nm or the surface roughness is not increased by more than 10% as compared to before the etching.

12. The method of claim 1, further comprising fabricating a high electron mobility transistor (HEMT) comprising:
obtaining the III-V semiconductor layer comprising a channel layer; and
performing at least one gate recess etch on the III-V semiconductor layer using the steps (a) and (b) comprising sequential self-limiting half-cycles of the oxidizing agent exposure and the hydrogen radical exposure.

13. The method of claim 12, further comprising a wafer having a diameter of at least 3 inches comprising the semiconductor layer, the method comprising performing a plurality of gate recess etches across a surface area of the wafer to form a plurality of etched surfaces, wherein a roughness of each of the etched surfaces is uniform to within 10%.

14. A high electron mobility transistor (HEMT) device comprising:
an InGaAs layer channel layer;
an InAlAs barrier layer on the channel layer;
an InGaAs cap layer on the channel layer
a gate recess formed in the InGaAs cap layer exposing a surface of the InAlAs barrier layer or a surface of an InP etch stop layer on the barrier layer; wherein the surface gate recess has a surface roughness of at most 0.15 nm over the area of the gate recess.

15. The HEMT device of claim 14, comprising gate metal formed in the gate recess, wherein an interface region of the gate recess with the gate metal has a lower electrical trap density relative to the interface region when the gate recess is formed by wet chemical etching.

16. A wafer comprising a plurality of the HEMTs of claim 14, wherein the gate recesses have an etch depth precision and surface roughness that is uniform to within 5%.

17. A system or apparatus for atomic layer etching of a III-V semiconductor material, the system comprising:
an atomic layer etching apparatus or reactor coupled to a source of hydrogen radicals;
an angled conduit coupling the source of hydrogen radicals to the surface of a sample when mounted on a sample holder in the reactor, the angled conduit preventing direct line of sight between the source and the surface of the sample.

18. The apparatus of claim 17, further comprising computer programmable to
instruct output of the reactants performing a first half-cycle comprising exposing a surface of the III-V semiconductor material to an oxidizing agent to form an oxide layer on the surface; and
performing a second half-cycle comprising exposing the oxide layer to hydrogen radicals to remove the oxide layer from the surface to form an etched surface; wherein the first half-cycle and the second half-cycle are each self-limiting.

19. The system or apparatus of claim 17, wherein the source of hydrogen radicals comprises an inductively coupled plasma source or microwave plasma remotely coupled to a sample holder in the ALE reactor by the angled conduit, the reactor further comprising a reactor chamber comprising the sample holder; a pump for reducing pressure in the reactor chamber; and a heater and temperature sensor coupled to the sample holder for controlling a temperature of the sample holder.

20. The system or apparatus of claim 17, wherein the ALE reactor further comprises a reactor chamber comprising a sample holder and the source of hydrogen radicals comprises a filament and a source of hydrogen containing gas (e.g., H₂) coupled to the reactor, wherein the filament is coupled to a power source for heating the filament to generate heat for thermal cracking to dissociate the hydrogen molecules in the reactor chamber, wherein the sample holder is further coupled to the source of hydrogen gas by the angled conduit, the system or apparatus further comprising a pump for reducing pressure in the reactor chamber; and the sample holder further coupled to a heater and temperature sensor for controlling a temperature of the sample holder.
